(19) United States
(12) Patent Application Publication
(10) Pub. No.: US 2024/0355676 A1
(43) Pub. Date: Oct. 24, 2024

(54) PROCESS FOR THIN ELECTROLESS DEPOSITION

(71) Applicant: APPLIED Materials, Inc., Santa Clara, CA (US)

(72) Inventor: Marvin L. Bernt, Kalispell, MT (US)

(73) Assignee: APPLIED Materials, Inc., Santa Clara, CA (US)

(21) Appl. No.: 18/304,626

(22) Filed: Apr. 21, 2023

(51) Int. Cl. H01L 21/768; H01L 21/762

(52) U.S. Cl. CPC H01L 21/76874; H01L 21/76251; H01L 21/76816

(57) ABSTRACT

A wafer-to-wafer assembly, including a first wafer having a dielectric, the dielectric having a first side and a second side, opposite the first side, at least one opening etched into first side of the dielectric, a plug seed layer disposed on the first side of the dielectric, a plug disposed in the at least one opening, a first thin layer deposited over the plug, and a second thin layer deposited over the first thin layer. The first thin layer, the second thin layer, or both the first thin layer and the second thin layer is deposited with electroless deposition. Further, a method of wafer-to-wafer bonding with the wafer-to-wafer assembly.

### BACKGROUND

Wafer-to-wafer or chip-to-wafer bonding is a process for joining two or more wafers or chips, generally without an intermediate layer. Wafer bonding has various applications, such as packaging, assembly, and integration for sensors and actuators. Wafer bonding is also important in enabling semi-conductor technology, such as micro-electromechanical systems (MEMS), micro-opto-electromechanical systems (MOEMS), and silicon-on-insulator (SOI) systems. Throughout the years, various methods of wafer bonding have been developed.

Conventionally, wafer-to-wafer bonding or chip-to-wafer bonding is done at high temperatures, such as 300° C. to 400° C. However, many devices cannot withstand such high temperatures during assembly of a package.

Accordingly, considerably effort is invested in finding lower temperature options for metal-metal bonds, either as direct bonds or hybrid bonds. It has been demonstrated that copper can be bonded at a much lower temperature, such as 100° C. to 150° C. by applying a thin layer or interfacial layer (IFL) onto a copper surface. This layer facilitates bonding by preventing copper oxide growth and creating a layer that diffuses easily into the copper at low temperature. However, challenges still arise with using a thin layer or IFL. Conventionally, the IFL is deposited onto the copper using physical vapor deposition (PVD). This requires post chemical mechanical planarization (CMP) lithography and resist lift-off steps to pattern the IFL onto the copper surface. In addition, challenges arise when attempting to deposit gold IFL directly onto copper surfaces. While theoretically gold is an excellent bonding interface, due in part to its high diffusion at low temperatures, when deposited directly on copper with electroless deposition, gold forms nodules that are unsuitable as a bonding interface.

Accordingly, wafer bonding interfaces and methods for bonding wafer-to-wafer assembly are needed.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, a wafer-to-wafer assembly is disclosed, including a first wafer having a dielectric, the dielectric having a first side and a second side, opposite the first side, at least one opening etched into first side of the dielectric, a plug seed layer disposed on the first side of the dielectric, a plug disposed in the at least one opening, a first thin layer deposited over the plug, and a second thin layer deposited over the first thin layer, where the first thin layer, the second thin layer, or both the first thin layer and the second thin layer is deposited with electroless deposition.

In some embodiments, a thickness of the first thin layer in combination with the second thin layer is about 2-7 nm. In some embodiments, the first thin layer is selected from nickel or silver. In some embodiments, the second thin layer is selected from gold, palladium, or a combination thereof.

In some embodiments, the wafer-to-wafer assembly is configured to bond the first wafer to a second wafer at a temperature of about 100-150° C.

In some embodiments, the second wafer includes a second dielectric having a second side, a second at least one opening etched into the second side of the second dielectric, a second plug seed layer disposed on the second side of the second dielectric, a second plug disposed in the second at least one opening, a third thin layer deposited over the second plug, and a fourth thin layer deposited over the third thin layer.

In some embodiments, a thickness of the third thin layer in combination with the fourth thin layer is about 2-7 nm. In some embodiments, the third thin layer is selected from nickel or silver. In some embodiments, the fourth thin layer is selected from gold, palladium, or a combination thereof. In some embodiments, the third thin layer, the fourth thin layer, or the third thin layer and the fourth thin layer is deposited into the opening electroless deposition.

In another aspect, a method of wafer-to-wafer bonding is disclosed, the method including providing a first wafer having a first dielectric, the first dielectric having a first side and a second side, opposite the first side, etching at least one opening into the first side of the first dielectric, depositing a plug seed layer on the first side of the first dielectric, depositing a plug into the at least one opening, depositing a first thin layer with electroless deposition over the plug, depositing a second thin layer with electroless deposition over the first thin layer, and bonding the first wafer to a second wafer.

In some embodiments, bonding the first wafer to the second wafer comprises bonding the first wafer to the second wafer at a temperature of about 100-150° C.

In some embodiments, the method further includes providing a second wafer having a second dielectric, the second dielectric having a third side and a fourth side opposite the third side, etching a second at least one opening into the third side of the second dielectric, depositing a second plug seed layer on the third side of the second dielectric, filling the second at least one opening with a second plug, depositing, with electroless deposition, a third thin layer over the second plug, and depositing, with electroless deposition, a fourth thin layer deposited over the third thin layer, before bonding the first wafer and the second wafer.

In some embodiments, a thickness of the first thin layer in combination with the second thin layer is about 2-7 nm. In some embodiments, the first thin layer is selected from nickel or silver. In some embodiments, the second thin layer is selected from gold, palladium, or a combination thereof. In some embodiments, a thickness of the third thin layer in combination with the fourth thin layer is about 2-7 nm. In some embodiments, the third thin layer is selected from nickel or silver. In some embodiments, the fourth thin layer is selected from gold, palladium, or a combination thereof.

In some embodiments, the method further includes polishing the plug with chemical mechanical planarization (CMP) before depositing the first thin layer with electroless deposition.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A is a conventional wafer, in accordance with the present technology;

FIG. 1B is an example wafer having a thin silver layer, in accordance with the present technology;

FIG. 1C is an example silver bonding interface, in accordance with the present technology;

FIG. 1D is an example wafer having a thin gold layer, in accordance with the present technology;

FIG. 1E is an example gold bonding interface, in accordance with the present technology;

FIG. 2 is an example wafer having a first thin layer and a second thin layer, in accordance with the present technology;

FIGS. 3A-3I are process diagrams illustrating an example method of forming a wafer-to-wafer bonding interface, in accordance with the present technology;

FIGS. 3J-3P are process diagrams of an example method of forming a wafer-to-wafer hybrid bonding interface, in accordance with the present technology;

FIG. 3Q is a process diagram of an alternative method of forming a wafer-to-wafer copper bonding interface, in accordance with the present technology;

FIG. 3R is a process diagram of an alternative method of forming a wafer-to-wafer copper bonding interface, in accordance with the present technology;

FIGS. 4A-4B show an example wafer-to-wafer hybrid bonding assembly bonded along a wafer-to-wafer bonding interface of a first wafer and a second wafer, in accordance with the present technology;

FIGS. 4C-4D show another example wafer-to-wafer copper to copper bonding assembly bonded along copper pillars of a first wafer and second wafer, in accordance with the present technology;

FIGS. 4E-4F show another example wafer-to-wafer copper to copper bonding assembly bonded along copper pillars of a first wafer and second wafer, in accordance with the present technology;

FIG. 5A is a flowchart of an example method of wafer-to-wafer bonding, in accordance with the present technology; and

FIG. 5B illustrates further steps of example method, a subset of the method of FIG. 5A, of wafer-to-wafer bonding, in accordance with the present technology.

### DETAILED DESCRIPTION

While illustrative embodiments have been illustrated and described, it will be appreciated that various changes can be made therein without departing from the spirit and scope of the invention.

Disclosed herein is a wafer-to-wafer assembly including a first thin layer and a second thin layer. In some embodiments, the first thin layer is silver, while the second thin layer is gold. In such embodiments, this can provide a smooth assembly, configured to bond a wafer to another wafer or a chip. Also disclosed herein is a method of wafer-to-wafer bonding with the wafer-to-wafer assembly as described herein.

It is not the inventor's intention to limit this technology only to semiconductor applications listed here. The disclosed technology herein has many potential applications where similar research challenges are involved. Depending on the feature structure, the disclosed technology can design controllable Cu or Cu alloys with different grain structure synthesis processes to be suitable with low temperature hybrid bonding.

Before explaining at least one embodiment of the presently disclosed and/or claimed inventive concept(s) in detail, it is to be understood that the presently disclosed and/or claimed inventive concept(s) is not limited in its application to the details of construction and the arrangement of the components or steps or methodologies set forth in the following description. The presently disclosed and/or claimed inventive concept(s) is capable of other embodiments or of being practiced or carried out in various ways. Also, it is to be understood that the phraseology and terminology employed herein is for the purpose of description and should not be regarded as limiting.

Unless otherwise defined herein, technical terms used in connection with the presently disclosed and/or claimed inventive concept(s) shall have the meanings that are commonly understood by those of ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the presently disclosed and/or claimed inventive concept(s) pertains. All patents, published patent applications, and non-patent publications referenced in any portion of this application are herein expressly incorporated by reference in their entirety to the same extent as if each individual patent or publication was specifically and individually indicated to be incorporated by reference.

All of the articles and/or methods disclosed herein can be made and executed without undue experimentation in light of the present disclosure. While the articles and methods of the presently disclosed and/or claimed inventive concept(s) have been described in terms of preferred embodiments, it will be apparent to those skilled in the art that variations may be applied to the articles and/or methods and in the steps or in the sequence of steps of the method described herein without departing from the concept, spirit, and scope of the presently disclosed and/or claimed inventive concept(s).

As utilized in accordance with the present disclosure, the following terms, unless otherwise indicated, shall be understood to have the following meanings.

The use of the word “a” or “an” when used in conjunction with the term “comprising” may mean “one”, but it is also consistent with the meaning of “one or more”, “at least one”, and “one or more than one”. The use of the term “or” is used to mean “and/or” unless explicitly indicated to refer to alternatives only if the alternatives are mutually exclusive, although the disclosure supports a definition that refers to only alternatives “and/or”. Throughout this application, the term “about” is used to indicate that a value includes the inherent variation of error for the quantifying device, the method being employed to determine the value, or the variation that exists among the study subjects. For example, but not by way of limitation, when the term “about” is utilized, the designation value may vary by plus or minus twelve percent, or eleven percent, or ten percent, or nine percent, or eight percent, or seven percent, or six percent, or five percent, or four percent, or three percent, or two percent, or one percent. The use of the term “at least one” will be understood to include one as well as any quantity more than one, including but not limited to, 2, 3, 4, 5, 10, 15, 20, 30, 40, 50, 100, etc. The term “at least one” may extend up to 100 or 1000 or more, depending on the term to which it is attached; in addition, the quantities of 100/1000 are not to be considered limiting, as lower or higher limits may also produce satisfactory results. In addition, the use of the term “at least one of X, Y, and Z” will be understood to include X alone, Y alone, and Z alone, as well as any combination of X, Y, and Z. The use of ordinal number terminology (i.e., “first”, “second”, “third”, “fourth”, etc.) is solely for the purpose of differentiating between two or more items and is not meant to imply any sequence or order or importance to one item over another or any order of addition, for example.

As used herein, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. The term “or combinations thereof” as used herein refers to all permutations and combinations of the listed items preceding the term. For example, “A, B, C, or combinations thereof” is intended to include at least one of: A, B, C, AB, AC, BC, or ABC and, if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

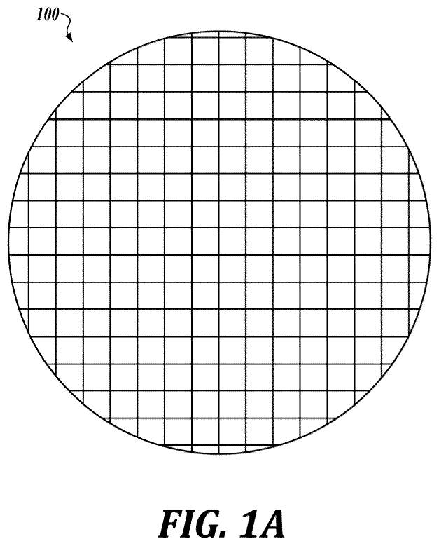

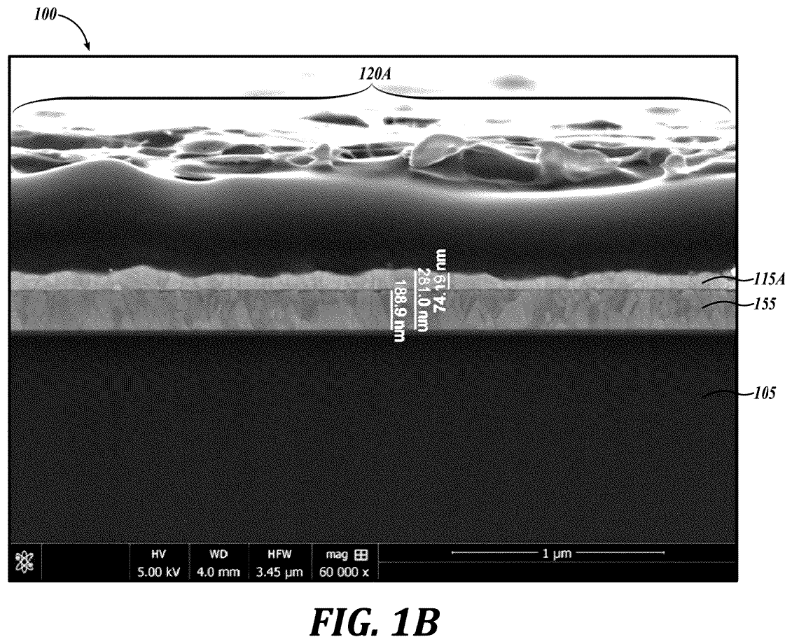

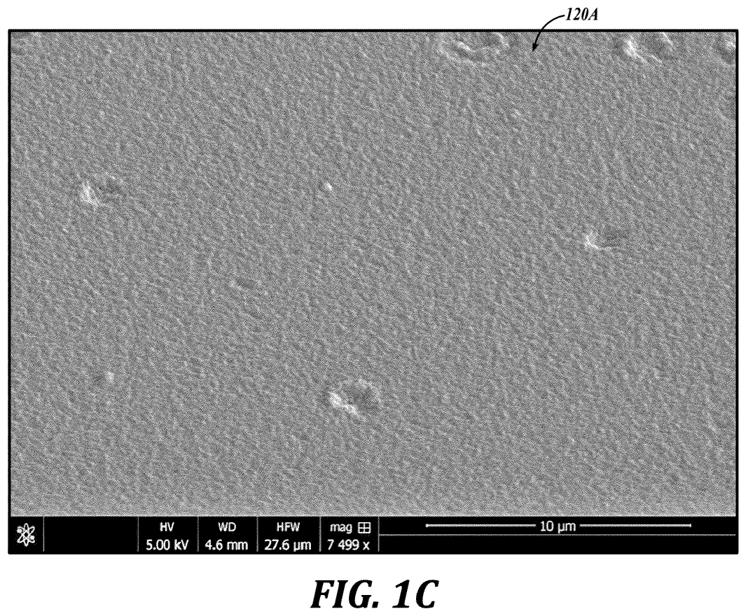

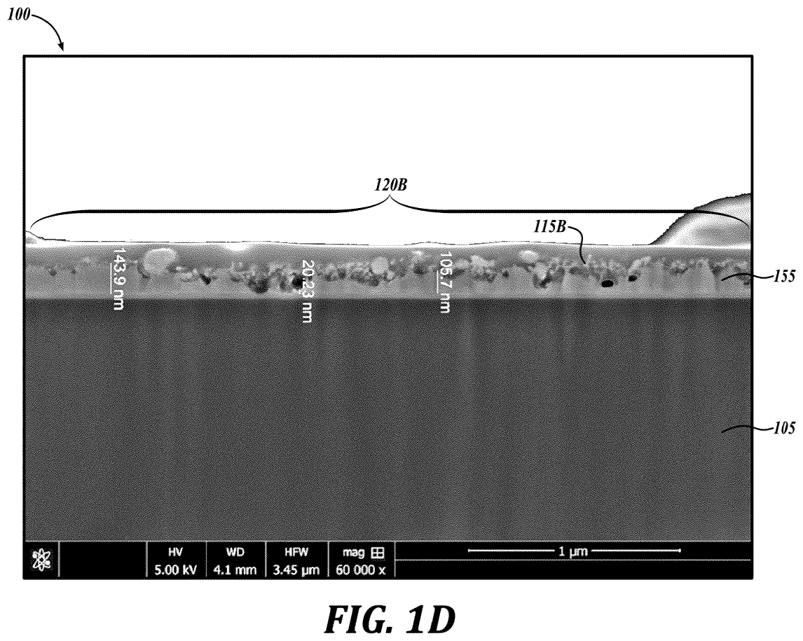

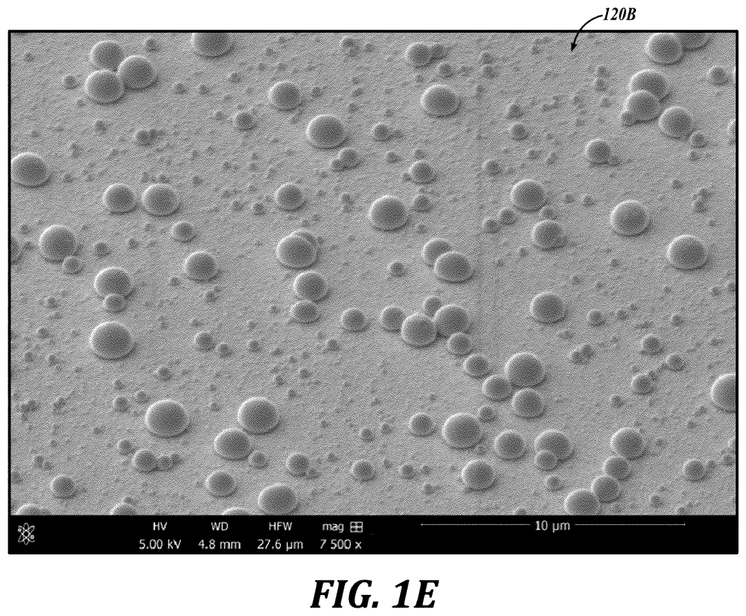

Turning now to the FIGURES, FIG. 1A is a conventional wafer 100, in accordance with the present technology. Wafer 100 may be made of silicon or another semiconductor material, and has the shape of a thin disc. In some applications, wafer 100 can be used to manufacture electronic integrated circuits (ICs). In such applications, wafer 100 is considered a dielectric, such as shown in FIGS. 1B-1E. In some embodiments, wafer 100 includes one or more openings, as described herein.

FIG. 1B is an example wafer 100 having a thin silver layer 115A, in accordance with the present technology. In some embodiments, wafer 100 includes a dielectric 105 and one or more openings. In some embodiments, the one or more openings may be copper interconnects.

As a non-limiting example, the series of layers in an opening include a dielectric 105, and a barrier layer (not shown in FIG. 1B). In some embodiments, the opening includes a plug 155. In some embodiments, the plug 155 may be copper, such as illustrated in FIG. 1B. In some embodiments, the opening may also include a copper cap.

The conventional fabrication of the opening may include a suitable deposition of a barrier layer on the dielectric 105 to prevent the diffusion of copper into the dielectric material of the dielectric 105. Suitable barrier layers include, for example, titanium (Ti), tantalum (Ta), titanium nitride (TiN), tantalum nitride (TaN), etc. In some embodiments, the barrier layer may be Mn-based, such as manganese (Mn) and manganese nitride (MnN).

In some embodiments, a seed layer may be deposited over the barrier layer. In the case of depositing copper in a feature, there are several exemplary options for the seed layer. First, seed layer may be a copper seed layer that is deposited using a Physical Vapor Deposition (PVD) technique. As another non-limiting example, the seed layer may be a copper alloy, such as copper manganese, copper cobalt, or copper nickel alloys. The seed layer may also be formed by using other deposition techniques, such as Chemical Vapor Deposition (CVD) or Atomic Layer Deposition (ALD).

Second, the seed layer may be a stack film, for example, including a liner layer and a PVD seed layer. A liner layer is a material used in between a barrier and a PVD seed layer to mitigate discontinuous seed issues and improve adhesion of the PVD seed. Liners are typically noble metals such as ruthenium (Ru), platinum (Pt), palladium (Pd), and osmium (Os), but the list may also include cobalt (Co) and nickel (Ni). Currently, Ru and Co liners are commonly formed on the wafer using the CVD technique; however, these liner layers may also be formed by using other deposition techniques, such as ALD or PVD.

Third, the seed layer may be a secondary seed layer. A secondary seed layer is similar to a liner layer, because the seed layer is typically formed from noble metals such as Ru, Pt, Pd, and Os, but the list may also include Co and Ni, and most commonly CVD-formed Ru and CVD-formed Co. (Like seed and liner layers, secondary seed layers may also be formed by using other deposition techniques, such as ALD or PVD.) The difference is that the secondary seed layer serves as the seed layer, whereas the liner layer is an intermediate layer between the barrier layer and the PVD Cu seed.

After a seed layer has been deposited according to one of the examples described above, the opening may include a seed layer enhancement (SLE) layer, which is a thin layer of deposited metal. As a non-limiting example, an SLE layer may be a copper layer having a thickness of about 2 nm. An SLE layer is also known as an electrochemically deposited seed (or ECD seed), which may be a conformal deposited layer.

An ECD copper seed is typically deposited using an alkaline chemistry including a dilute copper ethylenediamine (EDA) complex. ECD copper seed may also be deposited using other copper complexes, such as ethylenediamine, glycine, citrate, tartrate, ethylenediaminetetraacetic acid (EDTA), urea, etc., and may be deposited in a pH range of about 2 to about 11, about 3 to about 10, about 4 to about 10, or in a pH range of about 6 to about 10.

After the seed layer has been deposited according to one of the examples described above (which may also include an optional ECD seed), conventional ECD fill (or plug) and cap may be performed in the feature, for example, using acid plating chemistry at a pH of less than 1.0. Conventional ECD copper acid chemistry may include, for example, copper sulfate, sulfuric acid, methane sulfonic acid, hydrochloric acid, and organic additives (such as accelerators, suppressors, and levelers). An accelerator is used to enhance the plating rate inside the feature, the suppressor to suppress plating on the field, and the leveler to reduce the thickness variation of the plated copper over small dense features and wide ones. The combination of these additives enhances the bottom-up plating inside the feature relative to the plating on the field. Conventional ECD fill is typically bottom-up gap fill, super-fill, or super-conformal plating, having a goal of substantially void-free fill. While omitted in some FIGURES for clarity, each of these layers may be included in the wafer as described herein.

As shown in FIG. 1B, after the plug 155 is deposited, a thin layer (or IFL) 115A may be deposited. In one example, and as shown in FIG. 1B, the thin IFL 115A is made of silver. The thin IFL 115A provides a bonding interface 120A where the wafer 100 may bond with another wafer or a chip. In some embodiments, the silver IFL 115A is deposited by electroless deposition. The thin IFL 115A is configured to selectively deposit onto only the exposed metal of the plug 155.

FIG. 1C is an example silver bonding interface 120A, in accordance with the present technology. As shown in FIG. 1C, the silver bonding interface 120A is relatively smooth, having few defects. While the silver bonding interface 120A is sufficiently smooth to perform wafer-to-wafer bonding, silver may not have as high diffusivity as gold or palladium.

FIG. 1D is an example wafer 100 having a thin layer (or IFL) 115B of gold, in accordance with the present technology. In some embodiments, wafer 100 includes a dielectric 105, a plug 155, and a gold IFL 115B providing a gold bonding interface 120B. While theoretically, gold is an excellent IFL, due in part to its high diffusion at low temperatures, when deposited directly onto the plug 155, it forms nodules that may cause difficulties during bonding. As shown in FIG. 1D, the gold IFL 115B includes various defects on the gold bonding interface 120B.

FIG. 1E is an example gold bonding interface 120B, in accordance with the present technology. As can be clearly seen in FIG. 120B, nodules form on the gold bonding interface 120B and cause defects. As explained above, this can make gold IFL 115A deposited directly onto the plug 155 be less desirable as a bonding interface. In order to overcome these issues, a wafer having a first thin layer 115A and a second thin layer may be utilized.

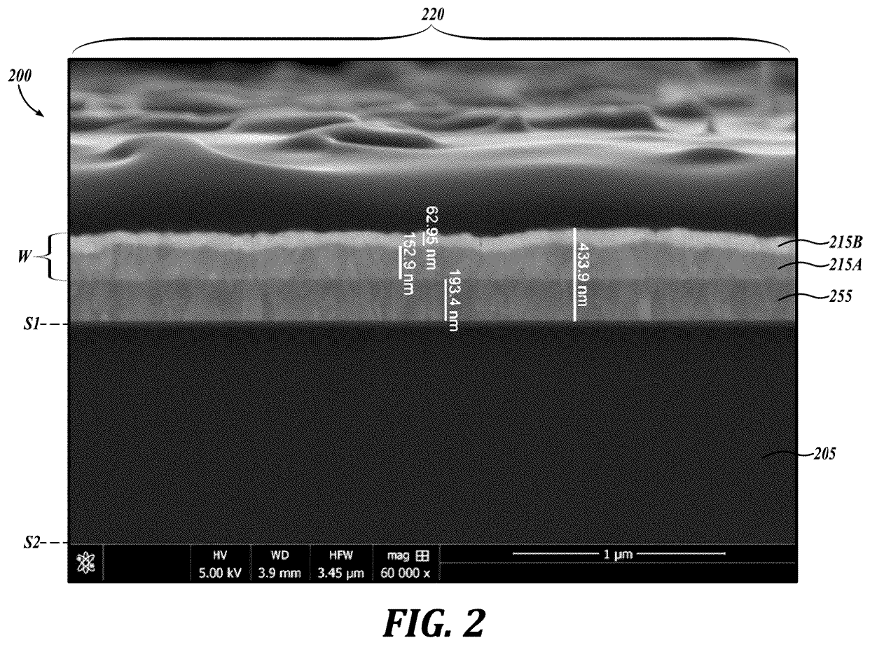

FIG. 2 is an example wafer 200 having a first thin layer 115A and a second thin layer 115B, in accordance with the present technology. In some embodiments, in order to provide the benefits of having a gold thin layer with higher diffusivity, while still producing a smooth, suitable bonding interface 220, a first thin layer 215A is deposited before a second thin layer 215B.

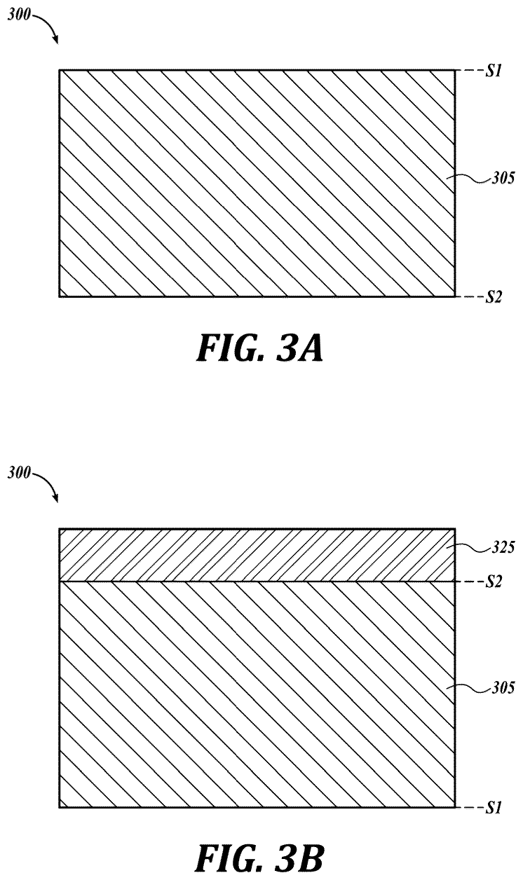

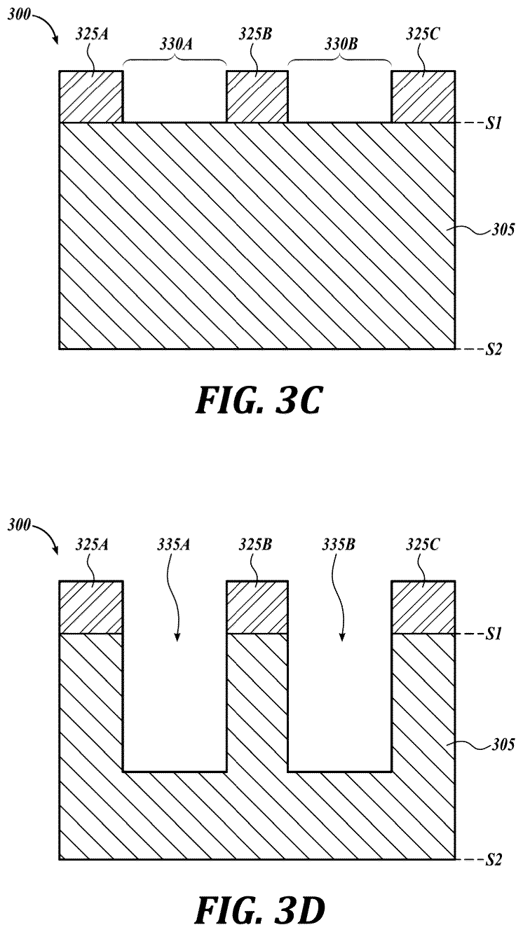

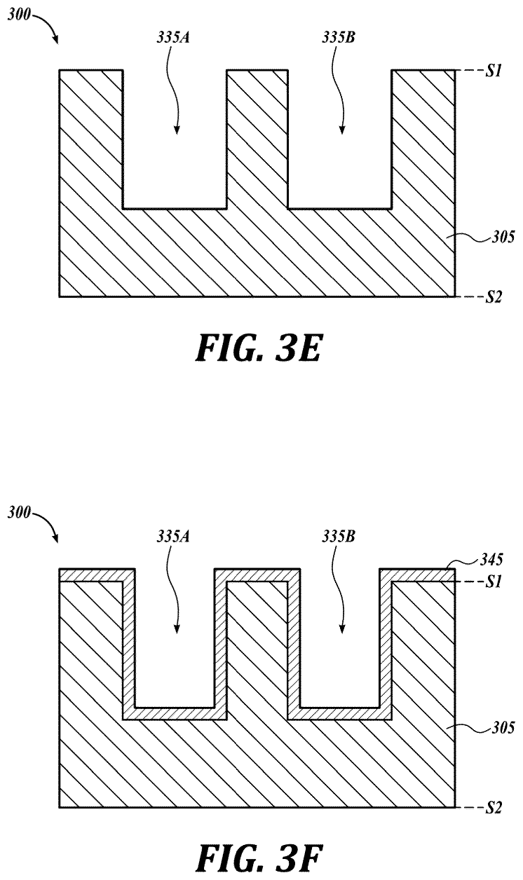

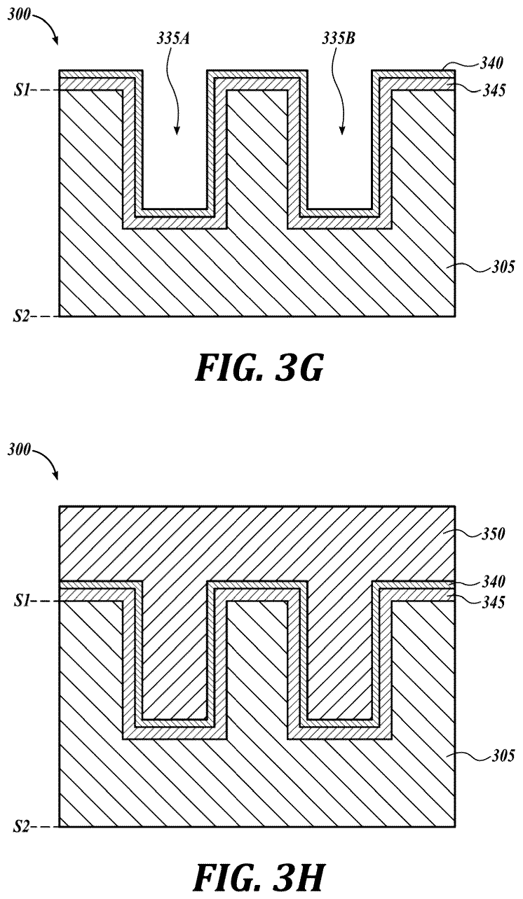

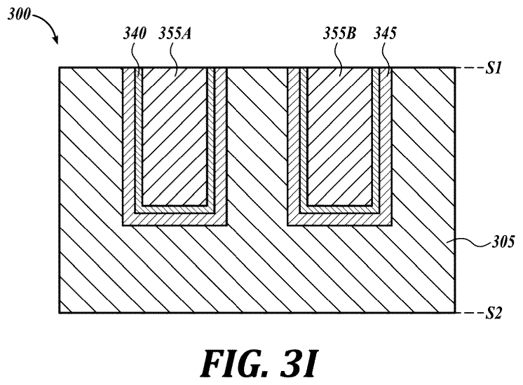

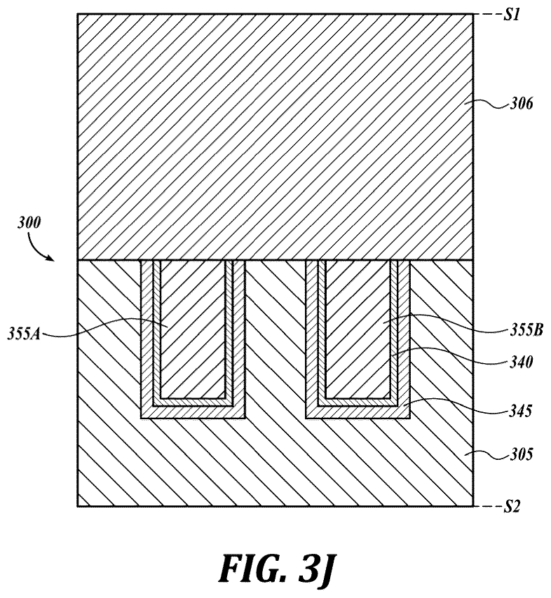

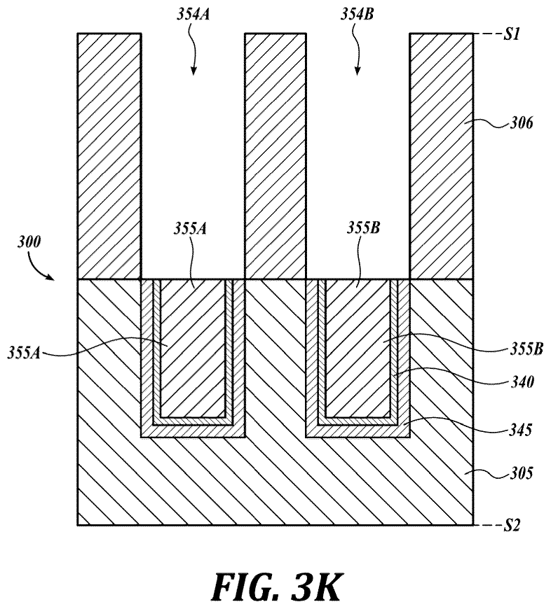

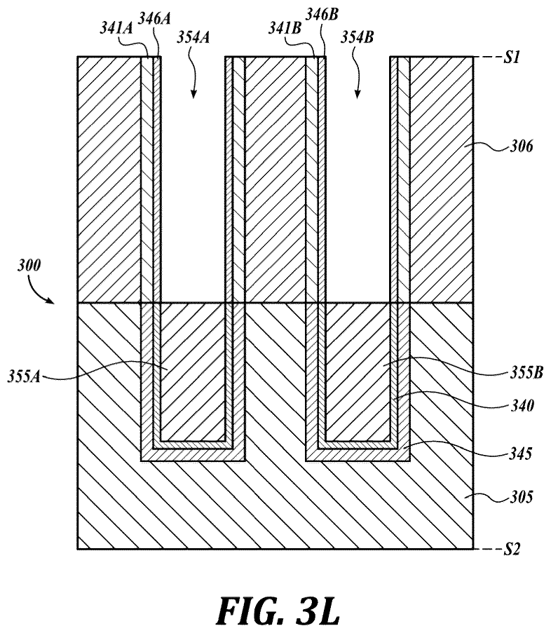

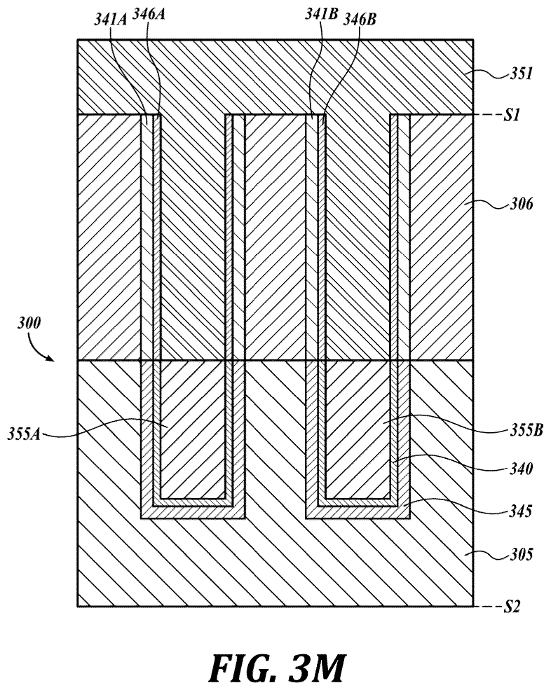

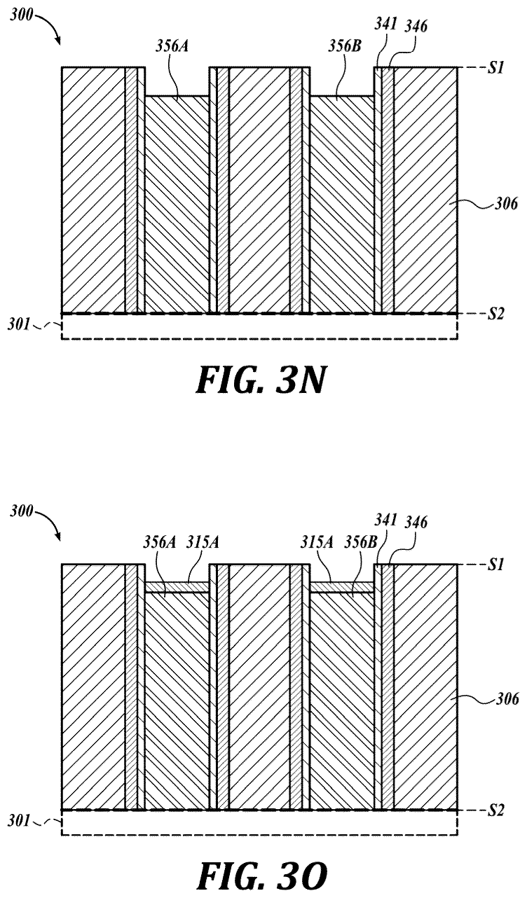

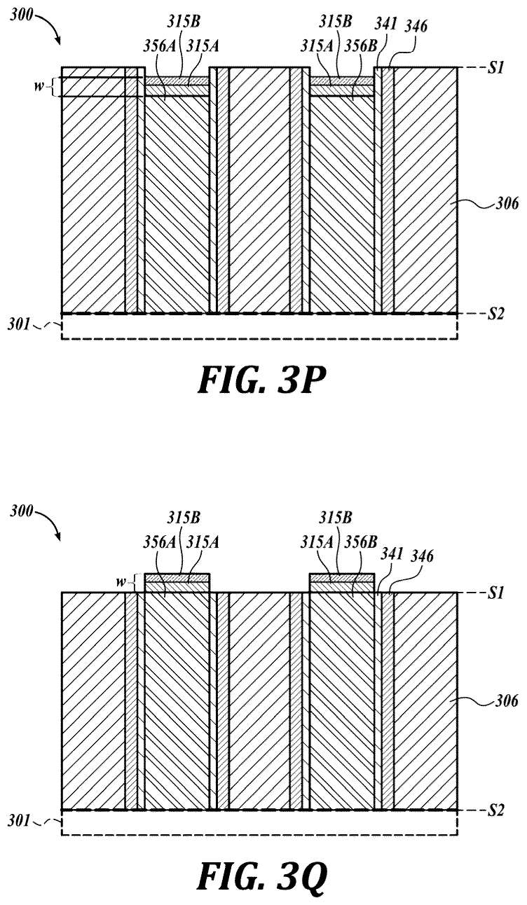

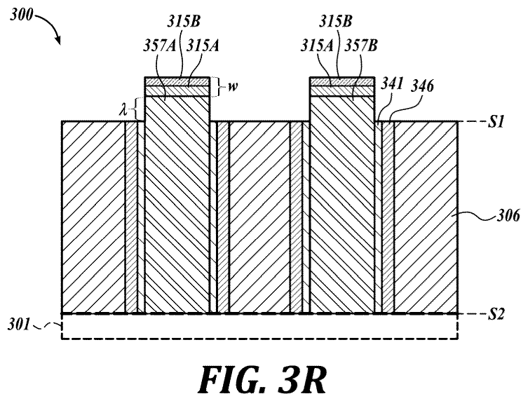

In some embodiments, a wafer-to-wafer bonding interface is disclosed, including a first wafer having a dielectric 205, the dielectric 205 having a first side S1 and a second side S2 opposite the first side S1, at least one opening etched into first side of the dielectric 205 (as shown in detail in FIGS. 3J-3R), a seed layer 210 disposed on the first side of the dielectric, a plug 255 is disposed in the at least one opening, a first thin layer 215B deposited over the plug 255, and a second thin layer 215B deposited over the first thin layer 215A. In some embodiments, the first thin layer 215A, the second thin layer 215B, or both the first thin layer 215A and the second thin layer 215B are deposited using electroless deposition. In some embodiments, electroless deposition allows the first thin layer 215A and the second thin layer 215B to be selectively deposited only onto the exposed metal of the plug 155. In some embodiments, a thickness W of the first thin layer 215A in combination with the second thin layer 215B is about 2-7 nm.

In some embodiments, the first thin layer 215A is selected from nickel or silver. In some embodiments, the first thin layer 215A is a combination (an alloy) of nickel and silver. In some embodiments, the second thin layer 215B is selected from gold, palladium, or a combination thereof. In some embodiments, the wafer-to-wafer bonding interface 220 is configured to bond the first wafer to a second wafer or a chip at a temperature of about 100-150° C.

FIGS. 3A-3R are process diagrams illustrating example methods of forming a wafer-to-wafer bonding interfaces, in accordance with the present technology.

FIG. 3A shows an example wafer 300. In some embodiments, the wafer 300 includes a substrate 305. The substrate 305 has a first side S1 and a second side S2 opposite the first side S1. The substrate 305 may be a dielectric material substrate.

In FIG. 3B, a layer of dielectric material 325 is deposited on the first side S1 of the substrate 305. In operation, the dielectric material 325 provides borders to demarcate the eventual vias (335A and 335B in FIG. 3D). In some embodiments, the dielectric material 325 may be omitted. In FIG. 3C, the dielectric material 325A, 325B, 325C remains after etching to form trenched 330A, 330B that may form vias 335A and 335B of FIG. 3D. In some embodiments, the dielectric material may be silicon dioxide, silicon nitride, or the like. While the trenched 330A, 330B are illustrated as having same width and depth, these trenched may have different sizes or depths through the silicon 325. In some embodiments, the trenches 335A, 335B are etched using a photoresist. It should be appreciated than any suitable photoresist may be used. While two trenched 330A, 330B are illustrated, it should be understood that other numbers of trenches 330 may be formed, including a single trench 330.

In FIG. 3D, one or more vias 335A, 335B are formed into the substrate 305 into the first side S1 of the substrate and extending towards the second side S2 of the substrate. In some embodiments, the vias 335A, 335B are formed so that they have the same width as the openings 330A, 330B. In some embodiments, the vias 335A, 335B are substantially equivalent in width and depth, but in other embodiments, the vias 335A, 335B may take different size or shape, and may be distinct from one another. In some embodiments, the vias 335A, 335B are formed with an etchant, such as iron acid or nitric acid. It should be understood that any suitable etchant may be used to form the vias 335A, 335B. While two vias 335A, 335B are illustrated, it should be understood that other number of vias 335 may be etched, including a single via 335. In FIG. 3E, the silicon layer 325A, 325B, is removed from the substrate 305. In some embodiments, the silicon layer 325A, 325B is removed with photoresist stripping.

In FIG. 3F, an oxide layer 345 is deposited onto the first side S1 of the substrate 305, so that it coats the first side S1 of the substrate 305 and lines the vias 335A, 335B. In some embodiments, the oxide layer 345 is a buffer oxide. In some embodiments, the oxide layer 345 is silicon oxide, nitride, silicon oxynitride, or the like. While an oxide layer 345 is shown in the illustrated embodiment, it should be understood that the oxide layer 345 may also be omitted. In FIG. 3G, a seed layer 340 is deposited over the oxide layer 345. In some embodiments, the seed layer 340 is a copper seed layer. In some embodiments, the seed layer 340 lines the vias 335A, 335B.

In FIG. 3H, a copper layer 350 is deposited into the vias 335A, 335B.

FIG. 3I shows two copper stacks 355A, 355B inside the vias 335A, 335B respectively. In some embodiments, the copper layer 350 extends past the height of the vias 335A, 335B and forms a layer on the first side S1 of the substrate 305, such as shown in FIG. 3H. In such embodiments, the copper layer 350 may be ground down to form two copper stacks 355A, 355B in the vias 335A, 335B (as shown in FIG. 3G) respectively. In some embodiments, the exposed seed layer 340 and oxide layer 345 may also be removed, such as with photoresist. Optionally, the stacks 355A, 355B may be polished with chemical mechanical planarization (CMP).

FIGS. 3J-3M are process diagrams illustrating a method of forming the wafer-to-wafer bonding interface described herein.

FIG. 3J illustrates a dielectric 306 being deposited onto the first side of the substrate 305. In some embodiments, the dielectric 306 has a first side S1 and a second side opposite the first side. As illustrated in FIG. 3J, the second side of the dielectric 306 may also be the first side of the substrate 305 (as shown in FIGS. 3N-3R). In some embodiments, the dielectric 306 is silicon dioxide, silicon nitride, silicon carbon nitride, and the like. In some embodiments, the dielectric 306 is 0.5 to 3 micrometers thick.

FIG. 3K shows the dielectric 306 being etched to form openings 354A, 354B. In some embodiments, the dielectric 306 is deposited over a wafer 300 with buried active devices. As described herein, buried active devices are the copper stacks 355A, 355B, oxide layer 345, and seed layer 340. In some embodiments, those devices connect to the dielectric 306 surface (i.e., S1 of dielectric 306) with copper lines and pads (as illustrated in FIG. 3M). In some embodiments, the active devices are buried in the dielectric 306 and then openings 356A, 356B are etched to expose it. In such embodiments, the dielectric 306 covers the copper seed layer 340 and the stacks 355A, 355B before the openings 354A, 354B are etched. In some embodiments, the openings 354A, 354B align with the copper stacks 355A, 355B.

FIG. 3L shows a plug oxide layer 341A, 341B and a plug seed layer 346A, 346B lining the openings 354A, 354B of the dielectric 306. In some embodiments, the plug buffer oxide layer 341 is the same material or materials of the oxide layer 345. Similarly, in some embodiments, the plug seed layer 346 is a copper seed layer and is the same material as the seed layer 340. In some embodiments, the plug oxide layer 341 and the plug seed layer 346 align with the oxide layer 345 and the seed layer 340. In some embodiments, the plug oxide layer 341, the plug seed layer 346, or both also line the bottom of the openings 354A, 354B, that is, where the dielectric 306 contacts the substrate 305.

In FIG. 3M, a copper fill 351 is deposited into the openings 354A, 354B. In some embodiments, the copper fill 351 extends past the height of the dielectric 306. In some embodiments, the copper fill 351 is grown from the plug seed layer 346A, 346B. In some embodiments, the copper fill 351 is made of the same copper as the copper stacks 355A, 355B.

FIGS. 3N-3R show process diagrams of example methods of forming wafer to wafer bonding interfaces, in accordance with the present technology. In FIG. 3N, the copper fill 351 is grinded down to form plugs 356A, 356B. The dielectric 306 has a first side S1 and a second side S2. The dashed box 301 represents where the dielectric 306 contacts the substrate 305. In some embodiments, 301 is the substrate 305 and the active buried devices (355A, 355B, 340, and 345 collectively), which have been omitted from FIGS. 3N-3R for clarity. In some embodiments, the dielectric 306 contacts the substrate 305 of FIGS. 3A-3M. In some embodiments, the substrate 305 may have any number or type of structures buried within it. In some embodiments, dashed box 301 can be any sort of finished wafer.

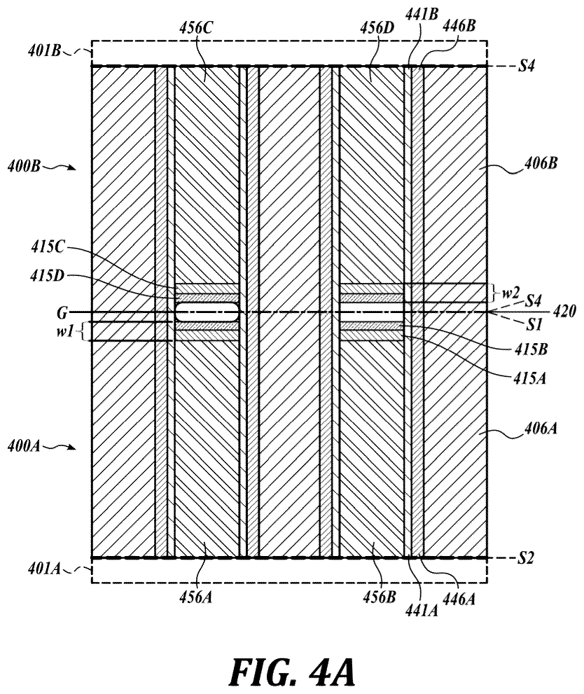

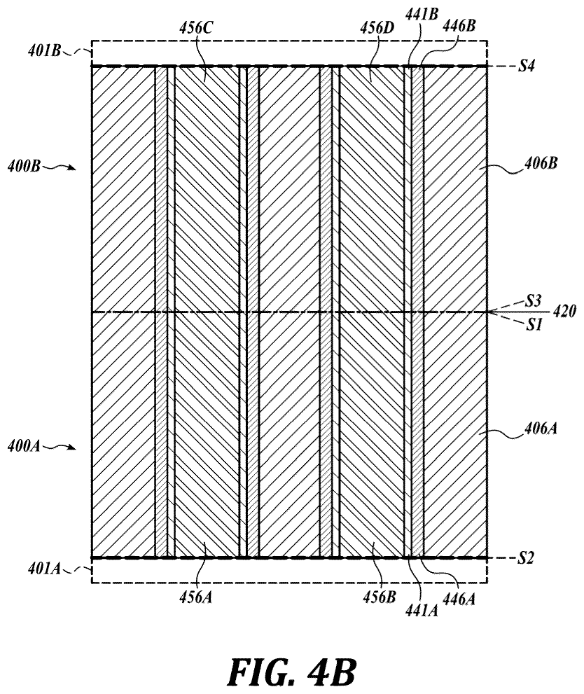

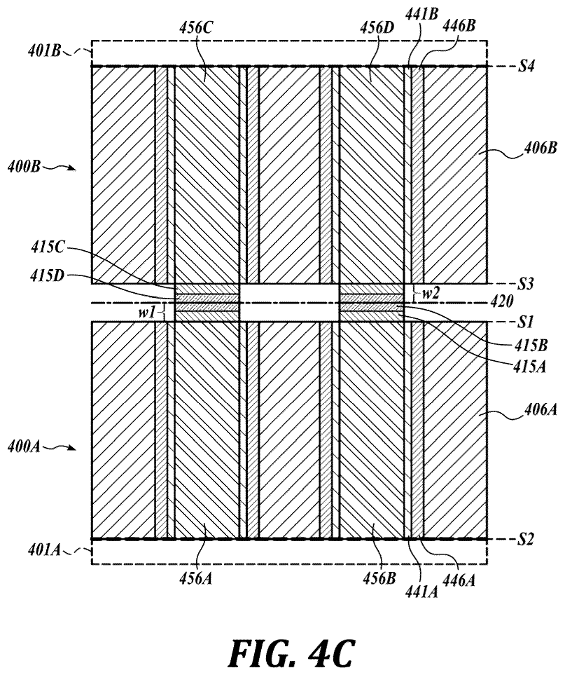

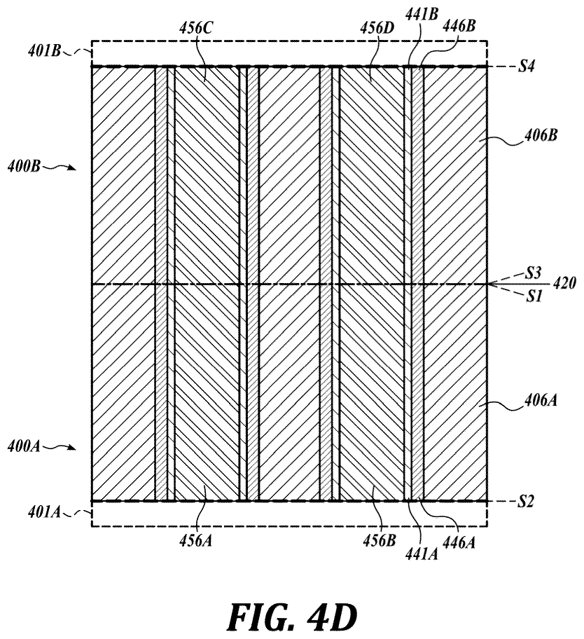

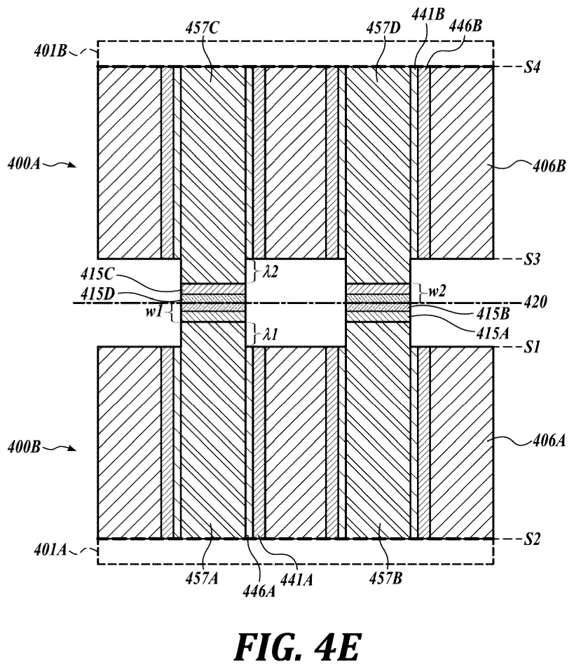

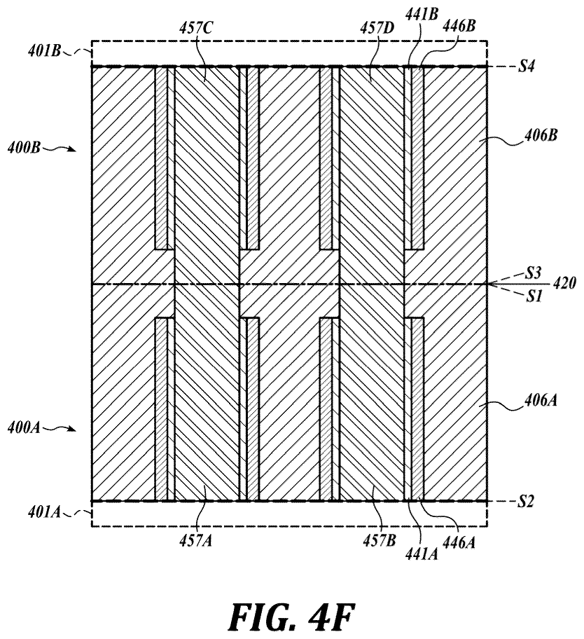

The plugs 356A, 356B may be grinded and then slightly dished to accommodate CTE expansion during the anneal step of the manufacturing process, as described in FIGS. 4A-4E. The final dishing may be determined by anneal conditions and the ultimate expansion of the metal in a captive volume. In some embodiments, this step may be omitted. In some embodiments, such as shown in FIG. 3N, the plugs 356A, 356B

In FIG. 3O, a first thin layer 315A is deposited over the plugs 355A, 355B. In some embodiments, the first thin layer 315A may be silver, nickel, or a combination of both silver and nickel. In some embodiments, the first layer 315A may be ground down so as to have a thickness of about 1-7 nm. In some embodiments, the first thin layer 315A may be ground to provide a relatively flat or smooth surface. In some embodiments, the first thin layer 315A is deposited using electroless deposition. In such embodiments, electroless deposition may be used to selectively deposit the first thin layer only onto the exposed metal of the plug 355A, 355B. In contrast to relative simplicity of the electroless deposition of metals layers over the copper plugs 356A, 356B, use of the physical vapor deposition (PVD) to deposit metal layers over the copper plugs 356A, 356B is more involved, requiring precise lithography, PVD onto the pads, resist (over the entire exposed surface), and then liftoff of the extra metal except on the pad.

In FIG. 3P, a second thin layer 315B may be deposited on top of the first thin layer 315A. In some embodiments, the second thin layer 315B is gold, palladium, or a combination (e.g., an alloy) of both gold and palladium. In some embodiments, the second layer 315B may be ground down so as to have a width of about 1-7 nm. In some embodiments, the second thin layer 315B may be ground to provide a relatively flat or smooth surface. In some embodiments, the second thin layer 315B is deposited using electroless deposition. In some embodiments, the second thin layer 315B forms the wafer-to-wafer bonding interface 320. When the first thin layer 315A is deposited before the second thin layer 315B, the second thin layer 315B forms a wafer-to-wafer bonding interface 320, even when the second thin film layer 315B is gold or palladium. In some embodiments, a thickness W1 of the first thin layer 315A combined with the second thin layer 315B is about 2-7 nm. In some embodiments, the second thin layer 315B forms a bonding interface 320, where a second wafer or a chip may be bonded, such as shown in FIG. 4. As explained in regards to the first thin layer 315A, when the second thin layer 315B is deposited with electroless deposition, the second thin layer 315B may be selectively deposited only onto the exposed metal of the first thin layer 315A. It should be understood that in some embodiments, the first thin layer 315A and the second thin layer 315B are nearly flush with the plugs 356A, 356B. In some embodiments, the first thin layer 315A and the second thin layer 315B in combination have a thickness w. In some embodiments, the thickness w is from 1 to 7 nm.

FIG. 3Q is a process diagram of an alternative method of forming a wafer-to-wafer bonding interface, in accordance with the present technology. In some embodiments, the plugs 356A, 356B are ground down so that the plugs 356A, 356B are flush with the height of the dielectric 306. In such embodiments, the first thin layer 315A and the second thin layer 315B extend slightly past the height of the dielectric 306. In some embodiments, the first thin layer 315A and the second thin layer 315B in combination have a thickness w. In some embodiments, the thickness w is from 1 to 7 nm.

FIG. 3R is an alternate embodiment of a copper-to-copper bonding interface, in accordance with the present technology. In some embodiments, provided herein is a copper-to-copper bonding interface. In some embodiments, the plug is polished to form a pillar 357A, 357B, each pillar 357A, 357 B extending a length of λ past the second first side S1 of the dielectric 306. In such embodiments, the first thin layer 315A is deposited selectively onto the pillars 357A, 357B. The second thin layer 315B is then deposited onto the first thin layer 315A. In such embodiments, both the first thin layer 315A and the second thin layer 315B may be deposited with electroless deposition. In different embodiments, the thickness of the first thin layer 315A may range from 1 nm to 7 nm, and the thickness of the second thin layer 315B may range from 1 nm to 7 nm. In some embodiments, the first thin layer 315A and the second thin layer 315B cap the entire exposed portion of the pillar 357A, 357B. In such embodiments, the first thin layer 315A and the second thin layer 315B also cover the sides of the pillar 357A, 357D. In such embodiments, the covering of the pillar 357A, 357B, may lead to corrosion resistance.

FIGS. 4A-4B show an example wafer-to-wafer hybrid bonding assembly bonded along a wafer-to-wafer bonding interface 420 of a first wafer 400A and a second wafer 400B, in accordance with the present technology. In some embodiments, such as shown in FIG. 4A, the first wafer 400A is the wafer 300 shown in FIG. 3P. In some embodiments, the first wafer 400A includes a first dielectric 406A with a first side S1 and a second side S2, an oxide layer 441A, a seed layer 446A, at least one plug 456A, 456B, a first thin layer 415A and a second thin layer 415B. In some embodiments, a thickness w1 of the first thin layer 415A in combination with the second thin layer 415B is about 1 to 7 nm. It should be understood that a first dashed box 401A represents the first substrate, such as substrate 305 in FIGS. 3A-3M. In some embodiments, first dashed box 401A is any finished wafer in any configuration. In some embodiments, first dashed box 401A is a substrate having buried active devices as described herein.

In some embodiments, the second wafer 400B includes a second dielectric 406B having a third side S3 and a fourth side S4, opposite the third side S3. It should be understood that a second dashed box 401B represents the a second substrate, which may be identical to substrate 305 in FIGS. 3A-3M. In some embodiments, the second dashed box 401B is any finished wafer in any configuration. In some embodiments, the second dashed box 401B is a substrate having buried active devices as described herein. In some embodiments, the second wafer 400B is made with the same process as wafer 300 in FIG. 3P. In some embodiments, a second at least one opening is etched into the third side S3 of the second dielectric 406B, a second seed layer 441B is deposited on the third side S3 of the second dielectric 406B, a second plug 456C, 456D disposed in the second at least one opening, a third thin layer 415C deposited over the second seed layer 440B, the second at least one opening, and the second plug 456C, 456D, and a fourth thin layer 415D deposited over the third thin layer 415C. In some embodiments, a thickness w2 of the third thin layer 415C in combination with the fourth thin layer 415D is about 2-7 nm. In some embodiments, the third thin layer 415C is selected from nickel or silver, or a combination of silver and nickel. In some embodiments, the fourth thin layer 415D is selected from gold, palladium, or a combination thereof. In some embodiments, the third thin layer 415C, the fourth thin layer 415D, or both the third thin layer 415C and the fourth thin layer 415D are deposited via electroless deposition.

In some embodiments, when the first wafer 400A and the second wafer 400B are connected via bonding interface 420, the space between the second thin layer 415A and the fourth thin layer 415D defines a gap G. In some embodiments, the first thin layer 415A, the second thin layer 415B, or both the first thin layer 415A and the second thin layer 415B are sacrificial layers. Further, in some embodiments, the third thin layer 415C and the fourth thin layer 415D are also sacrificial layers.

FIG. 4B is an example assembly where the sacrificial layers, first thin layer 415A, second thin layer 415B, third thin layer 415C, and fourth thin layer 415D have been dissolved, to form a hybrid bonding interface between both the copper plugs 455 and the dielectric of the first side S1 of the first wafer 400A and the third side S3 of the second wafer 400B along interface 420. In some embodiments, the bond of FIG. 4A is a first bond, the bond of FIG. 4B is a second bond, formed between outer dielectric surfaces of the first side S1 of the first dielectric 406A and the third side S3 of the second dielectric 406B, where the second bond is based on Van der Waal forces. In such embodiments, when the first wafer 400A and the second wafer 400B are bonded together, either or both thin layers (415A, 415B, 415C, 415D) of both wafers 400A, 400B dissolve to facilitate the bond. In some embodiments, the bonding interface 420 is a hybrid bonding interface, in that both the plugs 455A, 455B, 455C, 455D and dielectrics of the wafers, i.e., the first side S1 and the third side S3 of the first wafer 400A and the second wafer 400B, respectively, are bonded. In some embodiments, the bonding of the first wafer and the second wafer occurs at 100 to 150° C. In some embodiments, the dielectrics 406A, 406B have a lower coefficient of thermal expansion (CTE) than the plugs 456A, 456B, 456C, 456D. In such embodiments, at the temperature of 100 to 150° C., the plugs 456A, 456B, 456C, 456D expand to fill the gap G and bond the plugs 456A, 456B, 456C, 456D to one another. The first and second dielectrics 406A, 406B, having a lower CTE, do not expand, and are bonded together.

FIGS. 4C-4D show an example wafer-to-wafer bonding assembly, bonded along bonding interface 420. FIG. 4C is an example assembly where the first thin layer 415A and the second thin layer 415B extend slightly past the height of the dielectric 406A as shown in FIG. 3Q. It should be understood that the first thin layer 415A and the second thin layer 415B are not to scale, and in reality, the thinness of both the first thin layer 415A and the second thin layer 415B are only 2-7 nm thick in combination. Accordingly, in such embodiments, the first dielectric 406A and the second dielectric 406B are in contact with one another, or only separated by 2-7 nm. In some embodiments, the second wafer 400B is formed in the same process as shown in FIG. 3Q. Accordingly, second wafer 400B includes a plug oxide layer 446B, a plug seed layer 441B, and one or more plugs 456C, 456D.

FIG. 4D, is an example bonding assembly where the first wafer 400A and the second wafer 400B have been fully bonded together. In some embodiments, the first thin layer 415A, the second thin layer 415B, the third thin layer 415C, and the fourth thin layer 415D are sacrificial layers. FIG. 4D shows a copper-to-copper bonding interface, with the sacrificial layers removed. In such embodiments, when the first wafer 400A and the second wafer 400B are bonded together, either or both thin layers (415A, 415B, 415C, 415D) of both wafers dissolve to facilitate the copper to copper bond. It should be understood that the first thin layer 415A, the second thin layer 415B, the third thin layer 415C, and the fourth thin layer 415D are so thin that when the first thin layer 415A, the second thin layer 415B, the third thin layer 415C, and the fourth thin layer 415D dissolve, both the plugs 456A, 456B, 456C, 456D and the dielectrics 406A, 406B bond together. In some embodiments, the plugs 456A, 456B, 456C, 456D have a higher CTE than that of the dielectric 406A, 406B so that the copper expands to form the bond at 100 to 150° C.

FIGS. 4E-4F show an example wafer-to-wafer copper to copper bonding assembly bonded along copper pillars 457A, 457B, 457C, 457D of a first wafer 400A and second wafer 400B respectively, in accordance with the present technology. FIG. 4E is an example assembly where the copper plugs are pillars 457A, 457B, 457C, 457D. FIG. 4E corresponds to the embodiment shown in FIG. 3R. In some embodiments, a pillar 457A, 457B, 457C, 457D is a plug that extends past the first side of the dielectric at a length of A. In such embodiments, the assembly is formed with copper-to-copper bonding, as the pillars 457A, 457B, 457C, 457D are bonded together with the two thin layer 415A, 415B.

In some embodiments, the first thin layer 415A, the second thin layer 415B, the third thin layer 415C, and the fourth thin layer 415D are sacrificial layers. FIG. 4F shows a copper to copper bonding interface, with the sacrificial layers removed. In such embodiments, when the first wafer 400A and the second wafer 400B are bonded together, either or both thin layers (415A, 415B, 415C, 415D) of both wafers dissolve to facilitate the copper to copper bond. In such embodiments, the first and second dielectric 406A, 406B are made of polymers. In some embodiments, the polymers have a CTE higher than copper. Accordingly, when heat (between 100 to 150° C.) is applied to the wafers 400A, 400B, the first and second dielectrics 406A, 406B expand to form a second bond at the bonding interface 420, as shown in FIG. 4F.

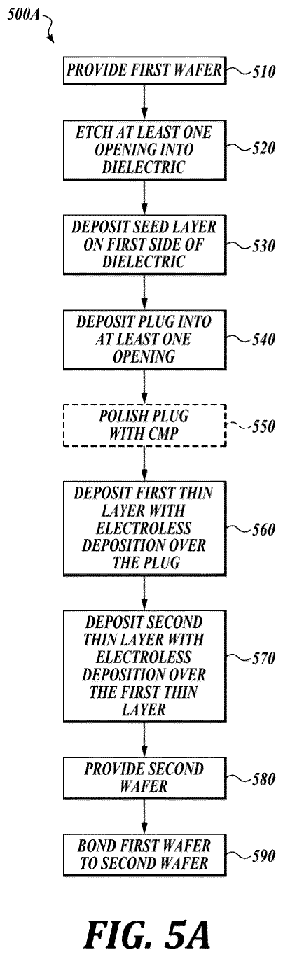

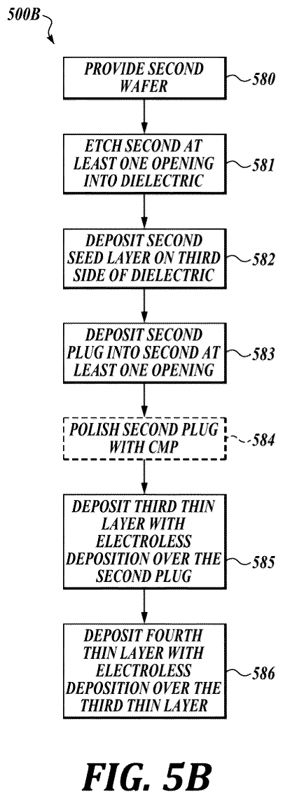

FIG. 5A is a flowchart of an example method 500A of wafer-to-wafer bonding, in accordance with the present technology. It is appreciated that the order in which some of the process blocks appear in process 500A should not be deemed limiting. Rather, one of ordinary skill in the art having the benefit of the present disclosure will understand that some of the process blocks may be executed in a variety of orders not illustrated, or even in parallel. Furthermore, the method may omit some steps or include the steps not shown in the illustrated flowchart. Method 500A begins in block 510. In block 510, a first wafer (such as wafer 400A in FIGS. 4A-4E) is provided. In some embodiments, the first wafer includes a dielectric (406A in FIGS. 4A-4E). In some embodiments, the dielectric has a first side and a second side opposite the first side (S1 and S2 in FIGS. 4A-4E). In some embodiments, the dielectric is a silicon-based dielectric. In some embodiments, the dielectric is silicon dioxide, silicon nitride, silicon carbon nitride, or a polymer.

In block 520, at least one opening is etched into the dielectric. In some embodiments, the at least one opening is etched on the first side of the dielectric, extending towards the second side of the dielectric. In some embodiments, multiple openings may be formed in the dielectric. In some embodiments, the openings may have the same width, depth, or both width and depth. In some embodiments, the openings align with one or more vias in a substrate below the dielectric, such as shown in FIG. 3K.

In block 530, a plug seed layer is deposited on the first side of the dielectric. In some embodiments, the plug seed layer is a copper seed layer. In some embodiments, the plug seed layer lines the trenches of the at least one opening, such as shown in FIG. 3L.

In block 540, a plug is deposited into the at least one opening. In some embodiments, a copper fill (such as copper fill 351 in FIG. 3M) is deposited into the at least one opening, and then ground down to form the plug. The plug may be copper, nickel, or a combination of copper and nickel. In operation, the plug conducts electrical current through the opening, to active devices buried in a substrate.

Optionally, in block 550, the plug is polished using CMP. In some embodiments, the plug may be dished to accommodate copper expansion upon binding with the second wafer. In some embodiments, the plug may be polished to form a pillar (such as shown in FIG. 3R) where the pillar extends past the height of the one or more openings.

In block 560, a first thin layer (such as first thin layer 415A) is deposited over the plug (or pillar). In some embodiments, the first thin layer is silver, nickel, or a combination thereof. In some embodiments, the first thin layer is deposited with electroless deposition. As described herein, electroless deposition (or chemical/autocatalytic plating) of the first thin layer may include the chemical reduction of a silver or nickel precursor to form metallic silver or nickel deposits on a pretreated surface, such as the plug or pillar.

In block 570, a second thin layer (such as second thin layer 415B) is deposited over the first thin layer. In some embodiments, the second thin layer is gold, palladium, or a combination thereof. In some embodiments, the second thin layer is also deposited using electroless deposition. As in the first thin layer, electroless deposition of the second thin layer may include the chemical reduction of a gold or palladium precursor to form gold or palladium deposits onto the first thin layer. In some embodiments, the thickness of the first thin layer in combination with the second thin layer is from 1 to 7 nm wide. In some embodiments, the second thin layer forms a wafer-to-wafer bonding interface.

In block 580, a second wafer is provided. In some embodiments, the second wafer is prepared as described in method 500B in FIG. 5B.

In block 590, the first wafer is bonded to the second wafer, thus forming an assembly of two wafers that are joined at the wafer-to-wafer bonding interface. In some embodiments, the first thin layer, the second thin layer, or both the first thin layer and the second thin layer are sacrificial layers. In such embodiments, when the first wafer and the second wafer are bonded together, either or both layer dissolves to facilitate the bond. In some embodiments, the bonding of the first wafer and the second wafer occurs at 100 to 150° C.

FIG. 5B is further steps of example method 500B, a subset of the method 500A of FIG. 5A, of wafer-to-wafer bonding, in accordance with the present technology. It is appreciated that the order in which some of the process blocks appear in process 500B should not be deemed limiting. Rather, one of ordinary skill in the art having the benefit of the present disclosure will understand that some of the process blocks may be executed in a variety of orders not illustrated, or even in parallel. In some embodiments, a second wafer is prepared to bond with the first wafer described in FIG. 5A. It should be understood that block 580 may follow block 570 of FIG. 5A.

In block 580, a second wafer as provided. In some embodiments, the second wafer includes a second dielectric having a third side and a fourth side opposite the third side (as shown in FIGS. 4A-4E). In some embodiments, the second dielectric is a silicon-based dielectric. In some embodiments, the second dielectric is silicon dioxide, silicon nitride, silicon carbon nitride, or a polymer.

In block 581, a second at least one opening is etched into the second dielectric. In some embodiments, the second at least one opening is etched on the third side of the second dielectric, extending towards the fourth side.

In block 582, a second plug seed layer is deposited onto the third side of the second dielectric. In some embodiments, the second plug seed layer is copper, nickel, or a combination thereof. In some embodiments, the second seed layer lines the second at least one opening.

In block 583, a second at least one plug is deposited into the second at least one opening. In some embodiments, the second at least one plug may be copper, nickel, or a combination thereof. As described herein, in some embodiments a second copper layer (such as copper layer 350 in FIG. 3H) is deposited into the second at least one via, and then ground down to form the at least one second plug or pillar.

Optionally, in block 584, the second at least one plug is polished with CMP. In some embodiments, the plug may be dished to accommodate copper expansion upon binding with a second wafer. In some embodiments, the plug may be polished or ground down to form a pillar (such as shown in FIG. 3R) where the pillar extends past the height of the one or more openings.

In block 585, a third thin layer (such as third thin layer 415C) is deposited over the second at least one plug. In some embodiments, the first thin layer is silver, nickel, or a combination thereof. In some embodiments, the first thin layer is deposited using electroless deposition. As described herein, electroless deposition (or chemical/autocatalytic plating) of the first thin layer may include the chemical reduction of a silver or nickel precursor to form metallic silver or nickel deposits on a pretreated surface, such as the second at least one plug or pillar.

In block 586, a fourth thin layer (such as fourth thin layer 415D) is deposited over the first thin layer. In some embodiments, the second thin layer is gold, palladium, or a combination thereof. In some embodiments, the second thin layer is also deposited using electroless deposition. As in the first thin layer, electroless deposition of the second thin layer may include the chemical reduction of a gold or palladium precursor to form gold or palladium deposits onto the first thin layer. In some embodiments, the thickness of the first thin layer in combination with the second thin layer is from 1 to 7 nm wide. In some embodiments, the second thin layer forms a wafer-to-wafer bonding interface. In some embodiments, the method then proceeds to block 590 in FIG. 5A.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A wafer-to-wafer bonded assembly, comprising:
a wafer including a dielectric, the dielectric having a first side and a second side opposite the first side;
at least one opening etched into the first side of the dielectric;
a plug seed layer disposed on the first side of the dielectric;
a plug disposed inside the at least one opening;
a first thin layer disposed over the plug; and
a second thin layer deposited over the first thin layer,
wherein the first thin layer, the second thin layer, or both the first thin layer and the second thin layer are deposited using electroless deposition.

2. The assembly according to claim 1, wherein a height of the plug exceeds a depth of the opening such that the plug extends above an outer surface of the dielectric.

3. The assembly according to claim 1, wherein a height of the plug corresponds to a depth of the opening such that an outer surface of the plug is flush with an outer surface of the dielectric.

4. The assembly according to claim 1, wherein a height of the plug is less than a depth of the opening such that the plug is recessed below an outer surface of the dielectric.

5. The assembly according to claim 1, wherein a thickness of the first thin layer in combination with the second thin layer is about 2-7 nm.

6. The assembly according to claim 1, wherein the first thin layer is selected from nickel, silver, or a combination thereof.

7. The assembly according to claim 1, wherein the second thin layer is selected from gold, palladium, or a combination thereof.

8. The assembly according to claim 1, wherein the wafer-to-wafer assembly is configured to form a bond at a temperature of about 100-150° C.

9. The assembly according to claim 7, wherein the wafer is a first wafer, the assembly further comprising a second wafer, wherein the second wafer comprises:
a second dielectric having a third side, and a fourth side opposite the third side;
a second at least one opening etched into the third side of the second dielectric;
a second plug seed layer disposed on the third side of the second dielectric;
a second plug disposed in the second at least one opening;
a third thin layer deposited over the second plug; and
a fourth thin layer deposited over the third thin layer,
wherein the bond is formed between the second thin layer and the fourth thin layer.

10. The assembly according to claim 8, wherein the bond is a first bond, and wherein a second bond is formed between outer dielectric surfaces of the first side of the first dielectric and the third side of the second dielectric, and wherein the second bond is based on Van der Waal forces.

11. The assembly according to claim 8, wherein a thickness of the third thin layer in combination with the fourth thin layer is about 2-7 nm.

12. The assembly according to claim 8, wherein the third thin layer is selected from nickel, silver, or a combination thereof.

13. The assembly according to claim 8, wherein the fourth thin layer is selected from gold, palladium, or a combination thereof.

14. A method of wafer-to-wafer bonding, the method comprising:
providing a first wafer having a first dielectric, the first dielectric having a first side and a second side, opposite the first side;
etching at least one opening into the first side of the first dielectric;
depositing a plug seed layer on the first side of the first dielectric;
depositing a plug into the at least one opening;
depositing a first thin layer using electroless deposition over the plug;
depositing a second thin layer using electroless deposition over the first thin layer; and
bonding the first wafer to a second wafer.

15. The method according to claim 14, wherein a height of the plug exceeds a depth of the opening such that the plug extends above an outer surface of the dielectric.

16. The method according to claim 14, wherein a height of the plug corresponds to a depth of the opening such that an outer surface of the plug is flush with an outer surface of the dielectric.

17. The method according to claim 11, wherein a height of the plug is less than a depth of the opening such that the plug is recessed below an outer surface of the dielectric.

18. The method according to claim 14, wherein the bonding the first wafer to the second wafer comprises bonding the first wafer to the second wafer at a temperature of about 100-150° C.

19. The method according to claim 14, wherein the method further comprises:
providing the second wafer having a second dielectric, the second dielectric having a third side and a fourth side opposite the third side;
etching a second at least one opening into the third side of the second dielectric;
depositing a second plug seed layer on the third side of the second dielectric;
filling the second at least one opening with a second plug;
depositing, using electroless deposition, a third thin layer over the second plug; and
depositing, using electroless deposition, a fourth thin layer deposited over the third thin layer, before bonding the first wafer and the second wafer.

20. The method according to claim 13, wherein the method further comprises:
polishing the first plug, the second plug, or both the first plug and the second plug with chemical mechanical planarization (CMP).
